(19) United States
(12) Patent Application Publication
(10) Pub. No.: US 2009/0152099 A1
(43) Pub. Date: Jun. 18, 2009

(54) METHOD FOR COATING A WORKPIECE

(76) Inventors: Andreas Kahny, Munchen (DE); Jurgen Steinwandel, Uhldingen-Muhlhofen (DE); Manuel Hertter, Munchen (DE)

Correspondence Address: MCANDREWS HELD & MALLOY, LTD, 500 WEST MADISON STREET, SUITE 3400, CHICAGO, IL, 60661, US

(21) Appl. No.: 12/335,135

(22) Filed: Dec. 15, 2008

Related U.S. Application Data
(63) Continuation of application No. PCT/DE2007/001053, filed on Jun. 14, 2007.

(30) Foreign Application Priority Data
Jun. 20, 2006 (DE) 102006028204.3

(51) Int. Cl. C23C 14/34

(52) U.S. Cl. 204/192.13

(57) ABSTRACT

The present technology relates to a method for coating a workpiece, in which a material is applied to the workpiece via a thermal spraying process that is monitored and evaluated to establish on-line process control. According to certain embodiments of the presently described method, infrared emissions of a spray jet are detected with the aid of at least one infrared camera, and properties of the spray jet are determined by analyzing the infrared emissions of the spray jet, which are detected by the at least one infrared camera.

### RELATED APPLICATIONS

This application is a continuation of International Application Serial No. PCT/DE2007/001053 (International Publication Number WO 2007/147388 A1), having an International filing date of Jun. 14, 2007 entitled “VERFAHREN ZUR BESCHICHTUNG EINES WERKSTUCKS” (“METHOD FOR COATING A WORKPIECE”). International Application No. PCT/DE2007/001053 claimed priority benefits, in turn, from German Patent Application No. 10 2006 028 204.3, filed Jun. 20, 2006. International Application No. PCT/DE2007/001053 and German Application No. 10 2006 028 204.3 are hereby incorporated by reference herein in their entireties.

### FEDERALLY SPONSORED RESEARCH OR DEVELOPMENT

[Not Applicable]

### MICROFICHE/COPYRIGHT REFERENCE

[Not Applicable]

### BACKGROUND OF THE INVENTION

The present technology relates generally to systems and methods using thermal sputtering for the coating of a workpiece. More specifically, the present technology relates to systems and methods for monitoring and evaluation of the thermal sputtering process to establish on-line process control.

Methods for coating of a workpiece using thermal sputtering are known in the art, for example, as described in international application No. WO 2004/029319 A2 (the “'319application”). The '319 application describes a method wherein a powdered material is applied to a workpiece using thermal sputtering, and where the sputtering process is monitored and evaluated to establish on-line process control. The method described in the '319 application optically monitors and evaluates on-line process control via a Charged Couple Device camera (a “CCD Camera”), wherein the CCD camera determines a light density distribution of the spray jet, which can be a plasma jet or a particle jet, for example. This procedure for monitoring and evaluation of the sputtering process is also referred to as the particle flux imaging (PFI) method.

The particle flux imaging method for monitoring and evaluation of the sputtering process during thermal sputtering requires the powdered material used for thermal sputtering to have a relatively strong intrinsic illumination in the visible wavelength range. However, intrinsic illumination is a material-specific property, and thus not all materials capable of being used in the thermal sputtering process can be detected in the spray jet by particle flux imaging. In particular, the particle flux imaging method is unsuitable for methods using thermal sputtering to apply a multi-component powder, such as a metal-polymer powder or metal-ceramic powder, for example. This is because the thermal sputtering of a metal-polymer powder process breaks down the polymer pyrolytically at temperatures greater than 500° C., thus a distinction cannot be made between the different components of the material powder during sputtering of a metal-ceramic polymer.

The particle flux imaging method known from the prior art therefore only permits restricted on-line process control of thermal sputtering.

It is therefore desirable to provide new methods and systems to monitor and evaluate the thermal sputtering process that provides on-line process control that overcomes the restrictions that occur with the present state of the art.

### BRIEF SUMMARY OF THE INVENTION

Certain embodiments of the present technology provide a new method for coating a workpiece, and for monitoring and evaluating the thermal sputtering process. In certain embodiments, a material is applied to the workpiece by thermal sputtering, wherein the sputtering process is monitored and evaluated to establish on-line process control. In certain embodiments, infrared emissions of the spray jet are detected by one or more infrared cameras. The properties of the sputtering process can be determined via infrared analysis of the infrared emissions of the spray jet as detected by the infrared camera.

Certain embodiments of the present technology present a method of establishing online process control for the coating of a workpiece via a sputtering process, for example, a thermal sputtering process. In certain embodiments, the method comprises the steps of: applying at least one coating material to at least one workpiece by at least one spray jet; detecting and recording at least two infrared emissions of at least two different molecules, atoms, or a combination of molecules and atoms emitted from the at least one spray jet by at least one infrared camera using at least two different infrared filters; and analyzing the recorded infrared emissions to determine the properties of the coating material emitted.

Certain embodiments of the present technology involve a thermal sputtering process involves the application of a multi-component powder to the workpiece. The multi-component powder can be a metal-polymer powder, for example. In certain embodiments, the multi-component powder is a metal-ceramic powder.

Certain embodiments present systems and methods wherein at least two different molecules, atoms, or combination thereof, are detected in the gas phase of the spray jet.

In certain embodiments, systems and methods are provided wherein one or more infrared cameras are used to detect and record infrared emissions, wherein each of the infrared cameras uses a different infrared filter.

### BRIEF DESCRIPTION OF SEVERAL VIEWS OF THE DRAWINGS

[Not Applicable]

### DETAILED DESCRIPTION OF THE INVENTION

According to certain embodiments of the presently described technology, infrared emissions of a spray jet are detected by one or more infrared camera, wherein the properties of the spray jet emissions can be obtained through infrared analysis of infrared emissions of the spray jet detected by the one or more infrared cameras.

In a proposed embodiment of the present technology, thermal sputtering is monitored via an infrared analysis of the spray jet. As a result of the monitoring process, it is possible to identify the different components within a spray jet. In particular, the monitoring process can determine non-homogeneities and evaporation rates of the spray jet. The present technology also makes it possible to selectively detect process-relevant molecules and/or atoms of the spray jet.

According to certain advantageous embodiments of the present technology, infrared emissions of different molecules and/or atoms of the spray jet can be detected using one or more infrared cameras by applying different infrared filters on the infrared cameras for the different molecules and/or atoms of the spray jet.

The present technology relates to a method for coating of a workpiece by thermal sputtering, applying a powdered material to the surface of the workpiece being coated. Thermal sputtering is a process known to one of ordinary skill in the art of the present technology, and the present systems and methods can be used in accordance with all embodiments of the thermal sputtering process presently known in the art.

According to certain embodiments of the present technology, the sputtering process of thermal sputtering can be monitored and evaluated to establish on-line process control. Namely, the infrared emissions of the spray jet are detected via at least one infrared camera. The properties of the jet spray can then be determined through infrared analysis of the infrared emissions of the spray jet detected by the infrared camera, or cameras.

Certain embodiments of the present technology can be applied to situations where a multi-component powder is applied to a workpiece, particularly where the multi-component powder is a metal-polymer powder or metal-ceramic powder, for example. Infrared emissions of different molecules and/or atoms of the spray jet can then be detected via the one or more infrared cameras. In particular, the process can detect infrared emissions of different molecules and/or atoms in the gas phase of the spray jet.

To achieve the detection of various or different molecules and/or atoms, certain embodiments employ the use of infrared filters adapted to the infrared emissions of the molecules and/or atoms being detected. Thus, it is possible to monitor the spray jet with several infrared cameras, a special infrared filter being assigned to each infrared camera, in order to detect the infrared emissions of different molecules and/or atoms (e.g., different substances) of the spray jet within the range of each infrared camera.

In certain embodiments, where the thermal sputtering process applies a metal-ceramic powder to the workpiece, aluminum oxide and zirconium oxide, as well as dimeric metal molecules, such as Ni₂ and Ti₂, for example, can be detected in the gas phase of the spray jet. Furthermore, in certain embodiments employing the use of metal-polymer powders, C—H molecules, such as CH₂ molecules in particular, can be detected.

The present technology has now been described in such full, clear, concise and exact terms as to enable a person familiar in the art to which it pertains, to practice the same. It is to be understood that the foregoing describes preferred embodiments and examples of the present technology and that modifications may be made therein without departing from the spirit or scope of the present technology as set forth in the claims. Moreover, while particular elements, embodiments and applications of the present technology have been shown and described, it will be understood, of course, that the present technology is not limited thereto since modifications can be made by those familiar in the art without departing from the scope of the present disclosure, particularly in light of the foregoing teachings and appended claims. Moreover, it is also understood that the embodiments shown in the drawings, if any, and as described above are merely for illustrative purposes and not intended to limit the scope of the present technology, which is defined by the following claims as interpreted according to the principles of patent law, including the Doctrine of Equivalents. Further, all references cited herein are incorporated in their entirety.

1. A method of establishing online process control for the coating of a workpiece via a sputtering process comprising the steps of:
applying at least one coating material to at least one workpiece by at least one spray jet;
detecting and recording at least two infrared emissions of at least two different molecules, atoms, or a combination thereof emitted from the at least one spray jet by at least one infrared camera using at least two different infrared filters; and
analyzing the recorded infrared emissions to determine the properties of the coating material emitted.

2. The method of claim 1, wherein the sputtering process involves the application of a multi-component powder to the workpiece.

3. The method of claim 2, wherein the multi-component powder is a metal-polymer powder.

4. The method of claim 2, wherein the multi-component powder is a metal-ceramic powder.

5. The method of claim 1, wherein the at least two different molecules, atoms, or combination thereof, are detected in the gas phase of the spray jet.

6. The method of claim 2, wherein the at least two different molecules, atoms, or combination thereof, are detected in the gas phase of the spray jet.

7. The method of claim 3, wherein the at least two different molecules, atoms, or combination thereof, are detected in the gas phase of the spray jet.

8. The method of claim 4, wherein the at least two different molecules, atoms, or combination thereof are detected in the gas phase of the spray jet.

9. The method of claim 1, wherein the sputtering process is a thermal sputtering process.

10. The method of claim 1, wherein said detecting and recording step uses at least two infrared cameras, each of the infrared cameras using a different infrared filter.
